(19) United States
(12) Patent Application Publication
(10) Pub. No.: US 2007/0145858 A1
(43) Pub. Date: Jun. 28, 2007

(54) Surface mounted resonator having cap means and method of forming the same using insulating ceramic substrate

(76) Inventors: In-Hwa Song, Gwangmyeong-si (KR); Ki-Hyun Kim, Suwon-si (KR); Sung-Jae Chang, Suwon-si (KR); Jae-Hyung Choi, Yongin-si (KR)

Correspondence Address: PLEVY & HOWARD & DARCY P.C., P.O. BOX 226, Fort Washington, PA, 19034, US

(21) Appl. No.: 11/643,209

(22) Filed: Dec. 21, 2006

(30) Foreign Application Priority Data
Dec. 23, 2005 (KR) 10-2005-0128476

(51) Int. Cl. H01L 41/047

(52) U.S. Cl. 310/320

(57) ABSTRACT

A surface mounted resonator having a cap means and a method of forming the same using an insulating ceramic substrate are provided, which can simplify a process of fabricating the surface mounted resonator. The surface mounted resonator includes: a cap means having upper and lower cap means, wherein the lower cap means has a vibration groove and the upper cap means has cap terminal connection electrodes; a resonance means disposed under the cap means and including upper, middle and lower resonance means, each of which has resonance electrodes and resonance holes disposed around the resonance electrodes; a condenser means having first to fifth condenser means sequentially stacked under the resonance means, wherein the first condenser means has another vibration groove, the second to fourth condenser means have condenser electrodes, and the fifth condenser means has condenser terminal connection electrodes; and connection wires for connecting the condenser terminal connection electrodes and the cap terminal connection electrodes, wherein the connection wires are disposed in contact with the resonance electrodes and the condenser electrodes, the vibration grooves in the first condenser means and the lower cap means are opposite to each other, and the resonance means is disposed in contact with the cap means and the condenser means at upper and lower surfaces.

### CROSS-REFERENCE TO RELATED APPLICATION

This application claims the benefit of Korean Patent Application No. 2005-0128476, filed Dec. 23, 2005, the disclosure of which is hereby incorporated herein by reference in its entirety.

### BACKGROUND OF THE INVENTION

1. Field of the Invention

The present invention relates to a surface mounted resonator and a method of forming the same and, more particularly, to a surface mounted resonator having a cap means and a method of forming the same using an insulating ceramic substrate.

2. Description of the Related Art

Recently, a ceramic resonator is being widely used in a mobile phone such as a global system for mobile communication (GSM) phone and a camera phone, a hard disk, or the like, to provide advantages to a user. While the ceramic resonator also generates a certain frequency like a quartz resonator, since the ceramic resonator can be minimized and cost effective in comparison with the quartz resonator, the demand for the ceramic resonator is increasing. In addition, the ceramic resonator uses mechanical resonance of a resonance plate formed of polycrystalline piezoelectric ceramic, thereby generating a very stable natural frequency. Therefore, it is possible for the ceramic resonator to implement electrical characteristics corresponding to a user's need using a piezoelectric constant and a geometry dimension of the resonance plate. Further, in order to generate a Mega-Hz of natural frequency, the ceramic resonator is varied to a surface mounted resonator having a condenser plate disposed under the resonance plate, thereby being mounted on a mobile phone, a DVD ROM, an MP3 Player, a memory stick, and so on.

However, since the surface mounted resonator includes a protective body in contact with a portion of the resonance plate, there is a probability of an electrical short between electrodes in the resonance plate and the protective body. The protective body may be formed of a conductive material. At this time, the initially designed surface mounted resonator cannot have a natural frequency due to the electrical short between the electrodes and the protective body. In addition, when the resonance plate and the condenser plate have different shapes from the protective body, it may be difficult to manufacture the surface mounted resonator due to misalignment of the protective body with the portion of the resonance plate. Therefore, the surface mounted resonator should be manufactured through complicated processes in order to appropriately maintain alignment between the protective body and the resonance plate.

Meanwhile, U.S. Pat. No. 6,976,295 discloses “METHOD OF MANUFACTURING A PIEZOELECTRIC DEVICE”, issued to Masayuki Kikushima et al.

According to Masayuki Patent, the method includes sequentially depositing a ceramic substrate, a quartz resonator, and a metal lid (or a ceramic lid). The metal lid is aligned with the ceramic substrate to be formed on the ceramic substrate. The quartz resonator is formed between the ceramic substrate and the metal lid. At this time, the metal lid is configured to be spaced apart from the quartz resonator and surround the quartz resonator.

However, when the metal lid and the ceramic substrate are misaligned with each other, the method may produce a piezoelectric device causing an electrical short between the metal lid and the quartz resonator. In addition, when the piezoelectric device uses a ceramic lid, the ceramic lid may be in contact with the quartz resonator depending on environment of the manufacturing process, thereby deteriorating resonance characteristics of the quartz resonator.

### SUMMARY OF THE INVENTION

In order to solve the foregoing and/or other problems, it is an aspect of the present invention to provide a surface mounted resonator having a cap plate formed of an insulating ceramic substrate suitably deposited on a condenser plate and a resonance plate.

It is another aspect of the present invention to provide a method of forming a surface mounted resonator having a cap plate using an insulating ceramic substrate to be suitably aligned with a condenser plate and a resonance plate, enabling mass production.

The foregoing and/or other aspects of the present invention may be achieved by providing a surface mounted resonator having a cap means and a method of forming the same using an insulating ceramic substrate.

The surface mounted resonator includes: a cap means having upper and lower cap means, wherein the lower cap means has a vibration groove and the upper cap means has cap terminal connection electrodes; a resonance means disposed under the cap means and including upper, middle and lower resonance means, each of which has resonance electrodes and resonance holes disposed around the resonance electrodes; a condenser means having first to fifth condenser means sequentially stacked under the resonance means, wherein the first condenser means has another vibration groove, the second to fourth condenser means have condenser electrodes, and the fifth condenser means has condenser terminal connection electrodes; and connection wires for connecting the condenser terminal connection electrodes and the cap terminal connection electrodes, wherein the connection wires are disposed in contact with the resonance electrodes and the condenser electrodes, the vibration grooves in the first condenser means and the lower cap means are opposite to each other, and the resonance means is disposed in contact with the cap means and the condenser means at upper and lower surfaces.

The method includes: forming a cap means having upper and lower cap means, wherein the lower cap means has a vibration groove and the upper cap means has cap terminal connection electrodes; forming a resonance means disposed under the cap means and having upper, middle and lower resonance means, each of which has resonance electrodes and resonance holes around the resonance electrodes; forming a condenser means having first to fifth condenser means sequentially stacked under the resonance means, wherein the first condenser means has another vibration groove, the second to fourth condenser means have condenser electrodes, and the fifth condenser means has condenser terminal connection electrodes; and forming connection wires for connecting the condenser terminal connection electrodes and the cap terminal connection electrodes, wherein the connection wires are disposed in contact with the resonance electrodes and the condenser electrodes, the vibration grooves in the first condenser means and the lower cap means are opposite to each other, and the resonance means is disposed in contact with the cap means and the condenser means at upper and lower surfaces.

### BRIEF DESCRIPTION OF THE DRAWINGS

These and/or other aspects and advantages of the present invention will become apparent and more readily appreciated from the following description of the embodiments, taken in conjunction with the accompanying drawings of which:

FIG. 1 is an exploded perspective view of a surface mounted resonator in accordance with the present invention;

FIGS. 2 and 3 are plan views of a cap substrate;

FIGS. 4 to 6 are plan views of a resonance substrate;

FIGS. 7 to 11 are plan views of a condenser substrate;

FIG. 12 is an exploded perspective view of a cap means taken along lines I-I′ and II-II′ of FIG. 2;

FIG. 13 is a partial perspective view of FIG. 12;

FIG. 14 is an exploded perspective view of a resonance means taken along lines I-I′ and II-II′ of FIG. 4;

FIG. 15 is a partial perspective view of FIG. 14;

FIG. 16 is an exploded perspective view of a condenser means taken along lines I-I′ and II-II′ of FIG. 7;

FIG. 17 is a partial perspective view of FIG. 16; and

FIG. 18 is an exploded perspective view of FIGS. 12, 14 and 16.

### DETAILED DESCRIPTION OF THE INVENTION

Reference will now be made in detail to the embodiments of the present invention, examples of which are illustrated in the accompanying drawings. The embodiments are described below in order to explain the present invention by referring to the figures.

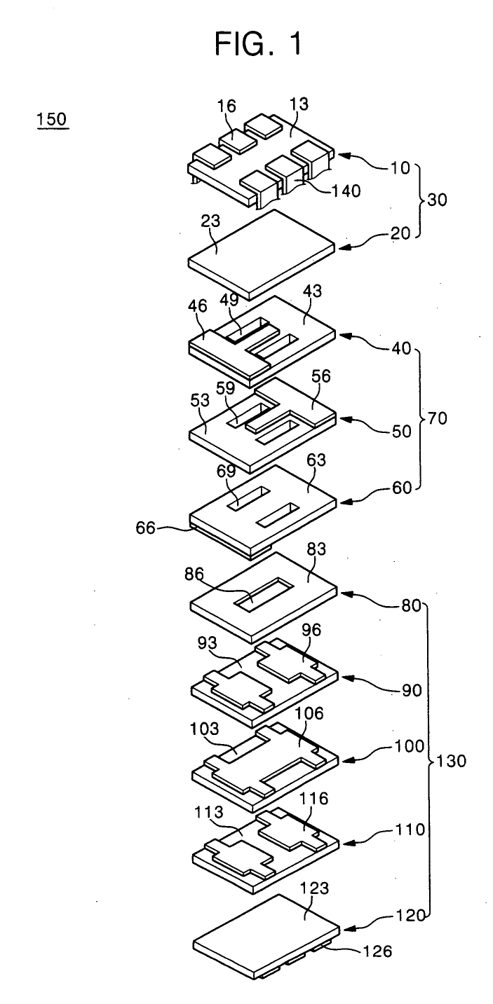

FIG. 1 is an exploded perspective view of a surface mounted resonator in accordance with the present invention.

Referring to FIG. 1, a cap means 30 is disposed in a surface mounted resonator 150. The cap means 30 includes upper and lower cap means 10 and 20. Upper and lower cap plates 13 and 23 are disposed in the upper and lower cap means 10 and 20, respectively. The upper and lower cap plates 13 and 23 have substantially the same area. Preferably, the upper and lower cap plates 13 and 23 are disposed parallel to each other. The upper and lower cap plates 13 and 23 in contact with each other are disposed in the cap means 30. Preferably, the upper and lower cap plates 13 and 23 are formed of a low temperature cofired ceramic (LTCC) material. The LTCC material may include ceramic and glass.

Cap terminal connection electrodes 16 are disposed on an upper surface of the upper cap plate 13. The cap terminal connection electrodes 16 are disposed in equal number directly across from one another at two opposite sides of the upper cap plate 13. On the other hand, the cap terminal connection electrodes 16 may be disposed in equal number in a staggered fashion at two opposite sides of the upper cap plate 13. The cap terminal connection electrodes 16 may be formed of a conductive material including silver (Ag). At this time, the upper and lower cap plates 13 and 23 may be sintered at a low temperature together with the cap terminal connection electrodes 16. In addition, a vibration groove (not shown) is formed at a lower surface of the lower cap plate 23. The vibration groove extends from the lower surface of the lower cap plate 23 toward an upper surface of the lower cap plate 23 by a predetermined depth. At this time, the vibration groove of the lower cap plate 23 may be disposed in the same form as another vibration groove 86 is of a first condenser plate 83.

A resonance means 70 is disposed under the cap means 30. The resonance means 70 may be disposed in contact with the cap means 30. The resonance means 70 includes upper, middle and lower resonance means 40, 50 and 60. The upper, middle and lower resonance means 40, 50 and 60 have upper, middle and lower resonance plates 43, 53 and 63 disposed therein, respectively. Thickness of the upper resonance plate 43 is the same as the sum of thicknesses of the middle and lower resonance plates 53 and 63. Each of the upper, middle and lower resonance plates 43, 53 and 63 has substantially the same area as the lower cap plate 23. Preferably, the upper, middle and lower resonance plates 43, 53 and 63 are disposed parallel to the lower cap plate 23. The middle resonance plate 53 contacts the upper and lower resonance plates 43 and 63 at its upper and lower surfaces and disposed in the resonance means 70. The upper, middle and lower resonance plates 43, 53 and 63 are preferably formed of a PbZrTiO3 (PZT) material.

Upper, middle and lower resonance electrodes 46, 56 and 66 are disposed on upper surfaces of the upper, middle and lower resonance plates 43, 53 and 63, respectively. The upper, middle and lower resonance electrodes 46, 56 and 66 have resonance characteristics. Preferably, the upper, middle and lower resonance electrodes 46, 56 and 66 are formed of a conductive material including silver (Ag). At least one upper resonance electrode 46, at least one middle resonance electrode 56 and at least one lower resonance electrode 66 are disposed on the upper, middle and lower resonance plates 43, 53 and 63, respectively. Each of the upper, middle and lower resonance electrodes 46, 56 and 66 has a shape of “ [symbol] ” or“ [symbol] ”. Preferably, the upper resonance electrode 46 and the middle resonance electrode 56 are disposed in a direction perpendicular to both end of the upper cap plate 13 to have shapes of “ [symbol] ” and “ [symbol] ” so that they are alternately disposed on the upper surfaces of the upper and middle resonance plates 43 and 53. Preferably, the lower resonance electrode 66 is positioned in a direction parallel to the upper resonance electrode 46 to have a shape of “ [symbol] ” to be disposed on a lower surface of the lower resonance plate 63. At this time, the vibration groove and another vibration groove 86 provide vibration spaces to the upper, middle and lower resonance electrodes 46, 56 and 66.

Resonance holes 49, 59 and 69 are formed at the upper, middle and lower resonance plates 43, 53 and 63. The resonance holes 49, 59 and 69 are disposed to overlap through the upper, middle and lower resonance plates 43, 53 and 63. Each of the upper, middle and lower resonance plates 43, 53 and 63 has at least two resonance holes 49, 59 or 69. Preferably, the resonance holes 49 of the upper resonance plates 43 are disposed around the vibration groove of the lower cap plate 23. The resonance holes 49 of the upper resonance plate 43 may overlap the vibration groove of the lower cap plate 23. In addition, the resonance holes 49 of the upper resonance plate 43 may partially overlap the vibration groove of the lower cap plate 23.

A condenser means 130 is disposed under the resonating means 70. The condenser means 130 may be disposed in contact with the resonance means 70. The condenser means 130 includes first to fifth condenser means 80, 90, 100, 110 and 120. The first to fifth condenser means 80, 90, 100, 110 and 120 have first to fifth condenser plates 83, 93, 103, 113 and 123 disposed therein, respectively. The first to fifth condenser plates 83, 93, 103, 113 and 123 are in contact with each other and sequentially deposited in the condenser means 130. Each of the first to fifth condenser plates 83, 93, 103, 113 and 123 has substantially the same area as the lower resonance plate 63. Preferably, the first to fifth condenser plates 83, 93, 103, 113 and 123 are disposed parallel to the lower resonance plate 63. Preferably, the first to fifth condenser plates 83, 93,103, 113 and 123 are formed of an LTCC material.

Another vibration groove 86 is formed of an upper surface of the first condenser plate 83. Preferably, the vibration groove 86 extends from the upper surface of the first condenser plate 83 to a lower surface thereof by a predetermined depth. Preferably, the vibration groove 86 is disposed between the resonance holes 69 of the lower resonance plate 63. The vibration groove 86 may be disposed to overlap the resonance holes 69 of the lower resonance plate 63, or partially overlap the resonance holes 69.

Upper, middle and lower condenser electrodes 96, 106 and 116 are disposed on upper surfaces of the second to fourth condenser plates 93, 103 and 113. Preferably, at least one upper condenser electrode 96 is disposed on the second condenser plate 93. Preferably, at least one middle condenser electrode 106 is disposed on the third condenser plate 103. In addition, preferably, at least one lower condenser electrode 116 is disposed on the fourth condenser plate 113. Preferably, the upper, middle and lower condenser electrodes 96, 106, 116 are formed of a conductive material including silver (Ag). Condenser terminal connection electrodes 126 are disposed on a lower surface of the fifth condenser plate 123.

When the cap terminal connection electrodes 16 are disposed in equal number directly across from one another at two opposite sides of the upper cap plate 13, the condenser terminal connection electrodes 126 may be disposed corresponding to each pair of directly opposite cap terminal connection electrodes. When the cap terminal connection electrodes 16 are disposed in equal number in a staggered fashion at two opposite sides of the upper cap plate 13, the condenser terminal connection electrodes 126 may be disposed corresponding to each cap terminal connection electrode.

Connection wires 140 are disposed to connect the cap terminal connection electrodes 16 and the condenser terminal connection electrodes 126. Preferably, the connection wires 140 are formed of a conductive material including silver (Ag). In addition, the connection wires 140 are disposed in contact with the upper, middle and lower resonance electrodes 46, 56 and 66 and the upper, middle and lower condenser electrodes 96, 106 and 116. For this purpose, the resonance means 70 may be disposed in contact with the cap means 30 and the condenser means 130 at its upper and lower surfaces. In addition, the vibration groove 86 of the first condenser plate 83 is disposed opposite to the vibration groove of the lower cap plate 23.

A method of forming a surface mounted resonator having a cap plate formed of an insulating ceramic material in accordance with the present invention will now be described with reference to the accompanying drawings.

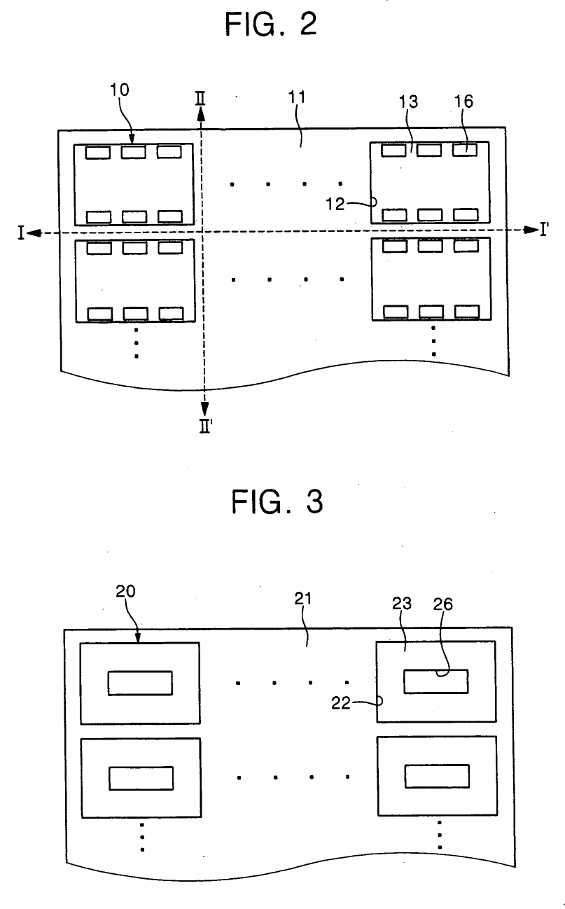

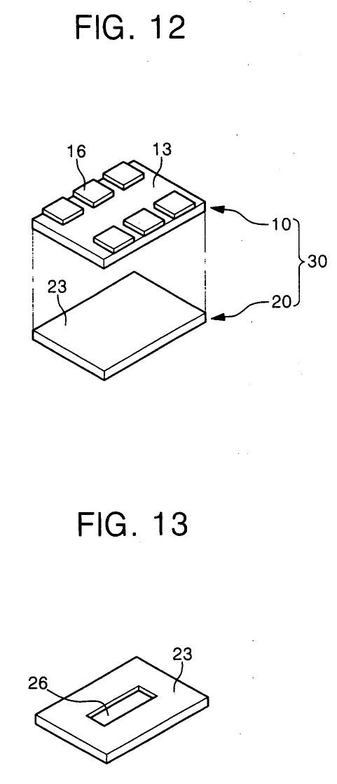

FIGS. 2 and 3 are plan views of a cap substrate, FIG. 12 is an exploded perspective view of a cap means taken along lines I-I′ and II-II′ of FIG. 2, and FIG. 13 is a partial perspective view of FIG. 12.

Referring to FIG. 2, an upper cap substrate 11 is prepared. The upper cap substrate 11 has an upper cap plate 13. The upper cap plate 13 and the upper cap substrate 11 have upper surfaces at different positions, respectively. At this time, at least one upper cap plate 13 is formed in a matrix on the upper surface of the upper cap substrate 11. The upper cap plate 13 and the upper cap substrate 11 are formed of a low temperature cofired ceramic (LTCC) material. The LTCC material includes ceramic and glass. On the other hand, upper cap regions 12 may be disposed on the upper cap substrate 11. The upper cap regions 12 and the upper cap substrate 11 have the same upper surface. The same number of upper cap regions 12 as the upper cap plates 13 are formed on the upper cap substrate 11 to define the upper cap plates 13. At this time, the upper cap regions 12 may be formed to have a predetermined area using a testing technique by dividing the upper cap substrate 11. The upper cap regions 12 may not be presented on the upper cap substrate 11.

Cap terminal connection electrodes 16 are formed on the upper cap plate 13. Preferably, the cap terminal connection electrodes 16 are disposed in equal number directly across from one another at two opposite sides of the upper cap plate 13. On the other hand, the cap terminal connection electrodes 16 may be disposed in equal number in a staggered fashion at two opposite sides of the upper cap plate 13. Preferably, the cap terminal connection electrodes 16 are formed by a conventional tape casting method. Preferably, the cap terminal connection electrodes 16 are formed of a conductive material including silver (Ag). The cap terminal connection electrodes 16 and the upper cap plate 13 constitute an upper cap means 10. On the other hand, the cap terminal connection electrodes 16 may be formed on the upper cap regions 12.

Referring to FIG. 3, a lower cap substrate 21 is prepared. The lower cap substrate 21 has a lower cap plate 23. The lower cap plate 23 and the lower cap substrate 21 have upper surfaces at different positions, respectively. At least one lower cap plate 23 is formed in a matrix on the lower surface of the lower cap substrate 21. At this time, the lower cap plates 23 are preferably formed corresponding to the upper cap plates 13 of FIG. 2. Preferably, the lower cap plate 23 and the lower cap substrate 21 are formed of an LTCC material.

Meanwhile, lower cap regions 22 may be set on the lower cap substrate 21. The lower cap regions 22 and the lower cap substrate 21 have the same upper surface. The same number of lower cap regions 22 as the lower cap plates 23 are formed on the lower cap substrate 21 to define the lower cap plates 23. At this time, the lower cap regions 22 may be formed to have a predetermined area using a testing technique by dividing the lower cap substrate 21. The lower cap regions 22 may not be presented on the lower cap substrate 21.

A vibration groove 26 is formed on the lower cap plate 23. Preferably, the vibration groove 26 has a predetermined depth extending from the lower cap plate 23 toward the lower cap substrate 21. The vibration groove 26 may be formed using a conventional punching technique and similar methods. The lower cap plate 23 and the vibration groove 26 constitute a lower cap means 20. On the other hand, the vibration groove 26 may be formed in the lower cap region 22.

Referring to FIGS. 2, 3, 12 and 13, an adhesive agent (not shown) may be interposed between the upper cap substrate 11 and the lower cap substrate 21. The adhesive agent serves to adhere an upper surface of the lower cap substrate 21 to a lower surface of the upper cap substrate 11. At this time, preferably, the upper surface and the lower surface of the upper and lower cap substrates 11 and 21 are oriented in different directions. The adhesive agent may be formed of a non-conductive adhesive agent.

Meanwhile, sidewalls of the upper and lower cap substrates 11 and 21 may be aligned on the same line. Continuously, the upper and lower cap substrates 11 and 21 are cut along row and column directions (lines I-I′ and II-II′ of FIG. 2) to have widths larger than those of the upper and lower cap plates 13 and 23, thereby forming a cap means 30 of FIG. 12. The upper and lower cap substrates 11 and 21 may be cut along row and column directions (lines I-I′ and II-II′ of FIG. 2) to have widths larger than those of the upper and lower cap regions 12 and 22, thereby forming the cap means 30 of FIG. 12. As a result, the upper and lower cap regions 12 and 22 define the upper and lower cap plates 13 and 23.

The cap means 30 includes upper and lower cap means 10 and 20. The cap means 30 is configured to have cap terminal connection electrodes 16 in the cap means 10 and a vibration groove in the lower cap means 20. At this time, the lower cap means 20 has a vibration groove 26 shown in FIG. 13 in the lower cap plate 23.

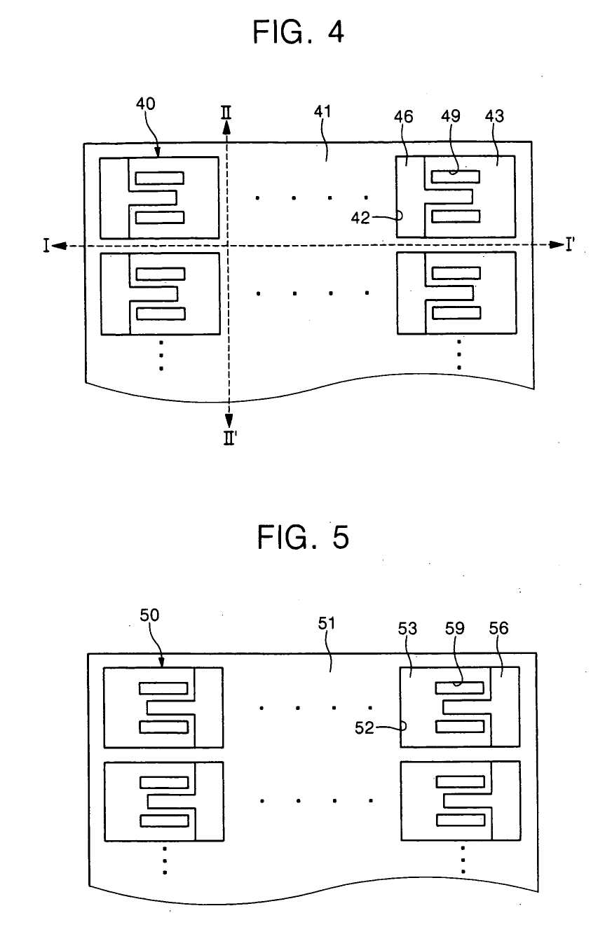

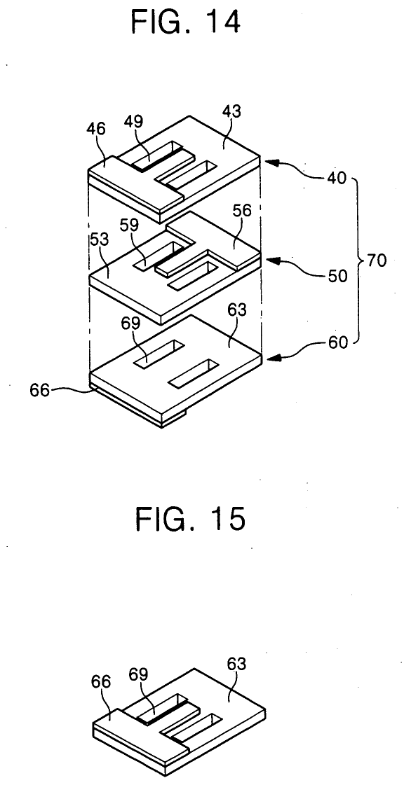

FIGS. 4 to 6 are plan views of a resonance substrate, FIG. 14 is an exploded perspective view of a resonance means taken along lines I-I′ and II-II′ of FIG. 4, and FIG. 15 is a partial perspective view of FIG. 14.

Referring to FIGS. 4 and 5, upper and middle resonance substrates 41 and 51 are prepared. The upper and middle resonance substrates 41 and 51 are formed to have upper and middle resonance plates 43 and 53, respectively. The upper and middle resonance plates 43 and 53 have upper surfaces at different positions from the upper and middle resonance substrates 41 and 51. At least one upper resonance plate 43 is formed in a matrix on the upper surface of the upper resonance substrate 41. Preferably, the middle resonance plates 53 are formed on the upper surface of the middle resonance substrate 51 to correspond to the upper resonance plates 43. Preferably, the upper and middle resonance plates 43 and 53 and the upper and middle resonance substrates 41 and 51 are formed of PZT (PbZrTiO₃).

Meanwhile, upper and middle resonance regions 42 and 52 may be set on the upper and middle resonance substrates 41 and 51. The upper and middle resonance regions 42 and 52 have substantially the same upper surfaces as the upper and middle resonance substrates 41 and 51. The same number of upper resonance regions 42 as the upper resonance plates 43 are formed on the upper resonance substrate 41 to define the upper resonance plates 43. The same number of middle resonance regions 52 as the middle resonance plates 53 are formed on the middle resonance substrate 51 to define the middle resonance plates 53. At this time, the upper and middle resonance regions 42 and 52 may be formed to have a predetermined area using a testing technique by dividing the upper and middle resonance substrates 41 and 51. The upper and middle resonance regions 42 and 52 may not be presented on the upper and middle resonance substrates 41 and 51.

Upper and middle resonance electrodes 46 and 56 are formed on the upper and middle resonance plates 43 and 53, respectively. Preferably, the upper and middle resonance electrodes 46 and 56 are disposed in a direction perpendicular to both sides of the upper cap plate 13 of FIG. 2 to have shapes of “ [symbol] ” and “ [symbol] ” so that they are alternately disposed on the upper surfaces of the upper and middle resonance plates 43 and 53. Preferably, the upper and middle resonance electrodes 46 and 56 are formed of a conductive material including silver (Ag). On the other hand, the upper and middle resonance electrodes 46 and 56 may be formed on the upper and middle resonance regions 42 and 52.

In addition, upper and middle resonance holes 49 and 59 are formed in the upper and middle resonance plates 43 and 53. The upper and middle resonance holes 49 and 59 are formed to overlap through the upper and middle resonance plates 43 and 53. The upper and middle resonance plates 43 and 53 have at least two upper and middle resonance holes 49 and 59, respectively. The upper resonance plate 43, the upper resonance electrode 46, and the upper resonance holes 49 constitute an upper resonance means 40. The middle resonance plate 53, the middle resonance electrode 56, and the middle resonance holes 59 constitute a middle resonance means 50. On the other hand, the upper and middle resonance holes 49 and 59 may be formed in the upper and middle resonance regions 42 and 52.

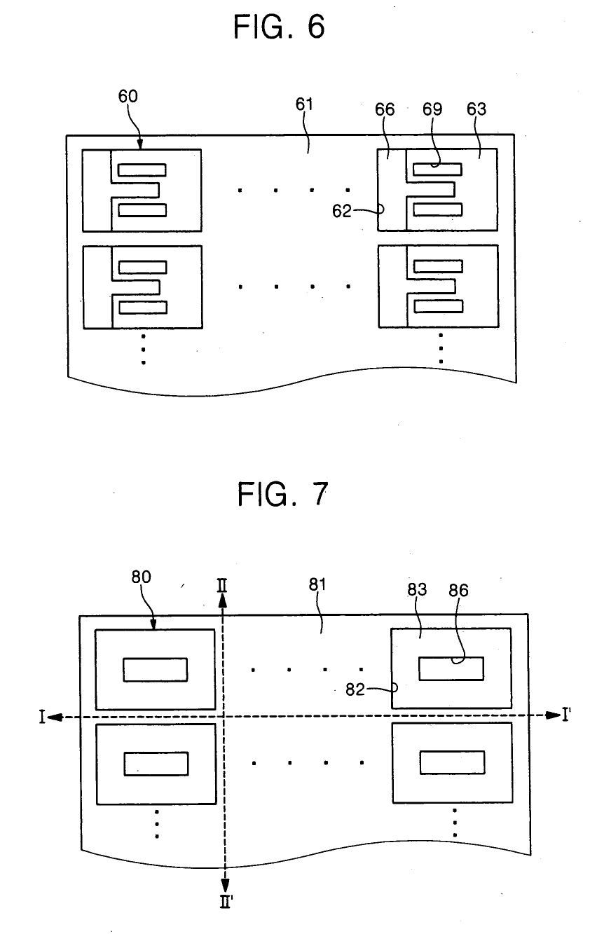

Referring to FIG. 6, a lower resonance substrate 61 is prepared. The lower resonance substrate 61 has a lower resonance plate 63. The lower resonance plate 63 and the lower resonance substrate 61 have lower surfaces at different positions. At least one resonance plate 63 is formed in a matrix on a lower surface of the lower resonance substrate 61. Preferably, the lower resonance plates 63 are formed on the lower surface of the lower resonance substrate 61 to correspond to the upper resonance plates 43 of FIG. 4. Preferably, the lower resonance plate 63 and the lower resonance substrate 61 are formed of PZT.

Meanwhile, lower resonance regions 62 may be set on the lower resonance substrate 61. The lower resonance regions 62 and the lower resonance substrate 61 have the same upper surface. The same number of lower resonance regions 62 as the lower resonance plates 63 are formed on the lower resonance substrate 61 to define the lower resonance plates 63. At this time, the lower resonance regions 61 may be formed to have a predetermined area using a testing technique by dividing the lower resonance substrate 61. The lower resonance region 62 may not be presented on the lower resonance substrate 61.

A lower resonance electrode 66 is formed on the lower resonance plate 63. Preferably, the lower resonance electrode 66 is positioned in a direction parallel to the upper resonance electrode 46 to have a shape of “ [symbol] ” to be disposed on the lower resonance plate 63. Preferably, the lower resonance electrode 66 is formed of a conductive material including silver. Preferably, lower resonance holes 69 are formed through the lower resonance plate 63. The lower resonance plate 63 has at least two lower resonance holes 69. Preferably, the lower resonance holes 69 are formed to overlap the middle resonance holes 59 of the middle resonance plate 53 of FIG. 5. The lower resonance plate 63, the lower resonance electrode 66, and the lower resonance holes 69 constitute a lower resonance means 60. On the other hand, the lower resonance electrode 66 may be formed on the lower resonance region 62. The lower resonance electrode 66 has resonance characteristics together with the upper and middle resonance electrodes 46 and 56.

In case that the upper, middle and lower resonance plates 43, 53 and 63 respectively have different upper surfaces from the upper, middle and lower resonance substrates 41, 51 and 61, the sum of thicknesses of the upper resonance substrate and resonance plate 41 and 43 is the same as that of the middle and lower resonance substrates 51 and 61, and the middle and lower resonance plates 53 and 63. Also, in case that the upper, middle and lower resonance plates 43, 53 and 63 respectively have the same upper surfaces as the upper, middle and lower resonance substrates 41, 51 and 61, thickness of the upper resonance plate 43 is the same as the sum of that of the the middle and lower resonance plates 53 and 63.

Referring to FIGS. 4, 6, 14 and 15, an adhesive agent (not shown) may be interposed between the upper, middle, and lower resonance substrates 41, 51 and 61. The adhesive agent serves to adhere the upper surface of the middle resonance substrate 51 to the lower surface of the upper resonance substrate 41 and the upper surface of the lower resonance substrate 61 to the is lower surface of the middle resonance substrate 51. At this time, preferably, the upper surfaces of the upper and middle resonance substrates 41 and 51 are oriented in the same direction. In addition, preferably, the upper surface and the lower surface of the middle and lower resonance substrates 51 and 61 are oriented in different directions. Preferably, the adhesive agent uses a non-conductive adhesive agent.

Meanwhile, sidewalls of the upper, middle and lower resonance substrates 41, 51 and 61 may be aligned on the same line. Continuously, the upper, middle and lower resonance substrates 41, 51 and 61 are cut along row and column directions (lines I-I′ and II-II′ of FIG. 4) to have widths larger than those of the upper, middle and lower resonance plates 43, 53 and 63, thereby forming a resonance means 70 of FIG. 14. The upper, middle and lower resonance substrates 41, 51 and 61 may be cut along row and column directions (lines I-I′ and II-II′ of FIG. 4) to have widths larger than those of the upper, middle and lower resonance regions 42, 52 and 62, thereby forming the resonance means 70 of FIG. 14. As a result, the upper, middle and lower resonance regions 42, 52 and 62 define the upper, middle and lower resonance plates 43, 53 and 63.

The resonance means 70 includes the upper, middle and lower resonance means 40, 50 and 60. The resonance means 70 is configured to have the upper, middle and lower resonance electrodes 46, 56 and 66 in the upper, middle and lower resonance means 40, 50 and 60, and the upper, middle and lower resonance holes 49, 59 and 69 around the upper, middle and lower resonance electrodes 46, 56 and 66.

The upper resonance holes 49 are formed around the vibration groove 26 of the lower cap plate 23 of FIG. 13. The upper resonance holes 49 may be formed to overlap the vibration groove 26 of the lower cap plate 23. The upper resonance holes 49 may be formed to partially overlap the vibration groove 26 of the lower cap plate 23. At this time, the lower resonance means 60 has the lower resonance holes 69 in the lower resonance plate 63, and the lower resonance electrode 66 on the lower resonance plate 63 as shown in FIG. 15.

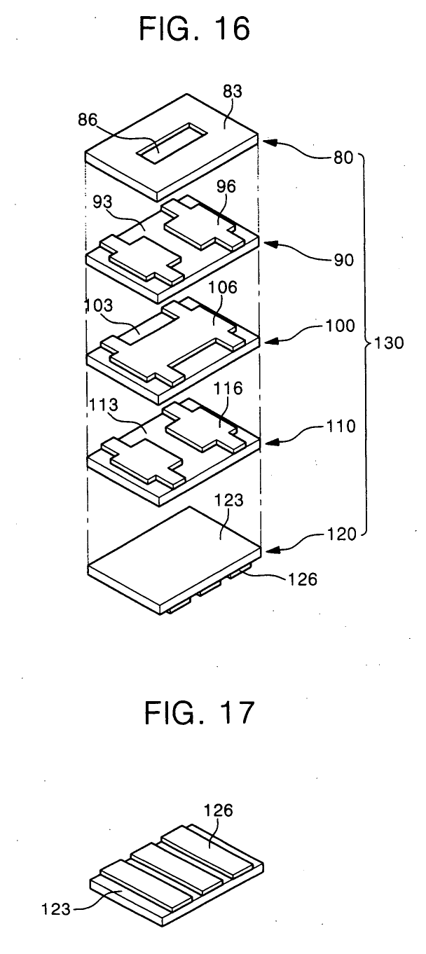

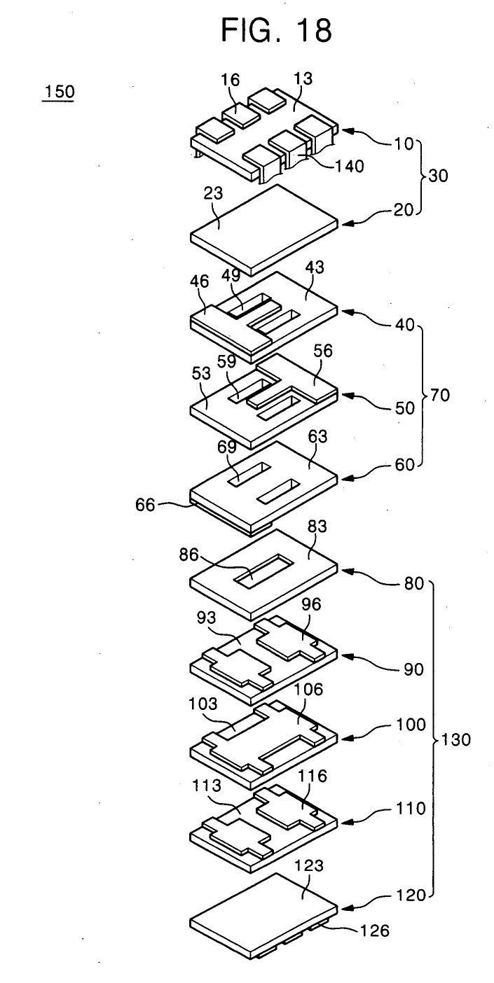

FIGS. 7 to 11 are plan views of a condenser substrate, FIG. 16 is an exploded perspective view of a condenser means taken along lines I-I′ and II-II′of FIG. 7, FIG. 17 is a partial perspective view of FIG. 16, and FIG. 18 is an exploded perspective view of FIGS. 12,14 and 16.

Referring to FIG. 7, a first condenser substrate 81 is prepared. The first condenser substrate 81 has a first condenser plate 83. The first condenser plate 83 and the first condenser substrate 81 have upper surfaces at different positions. At least one first condenser plate 83 is formed in a matrix on an upper surface of the first condenser substrate 81. Preferably, the first condenser plate 83 and the first condenser substrate 81 are formed of LTCC.

Meanwhile, first condenser regions 82 may be set on the first condenser substrate 81. The first condenser regions 82 and the first condenser substrate 81 have the same upper surface. The same number of condenser regions 82 as the first condenser plates 83 are formed on the first condenser substrate 81 to define the first condenser plates 83. At this time, the first condenser regions 82 may be formed to have a predetermined area using a testing technique by dividing the first condenser substrate 81. The first condenser regions 82 may not be presented on the first condenser substrate 81.

Another vibration groove 86 is formed on the first condenser plate 83. Preferably, the vibration groove 86 has a predetermined depth extending from the first condenser plate 83 toward the first condenser substrate 81. The vibration groove 86 may be formed using a conventional punching technique or similar methods. The first condenser plate 83 and the vibration groove 86 constitute a first condenser means 80. On the other hand, the vibration groove 86 may be formed in the first condenser region 82. The vibration groove 86 of FIG. 7 and the vibration groove 26 of FIG. 3 provide vibration spaces to the upper, middle and lower resonance electrodes 46, 56 and 66 of FIGS. 4 to 6.

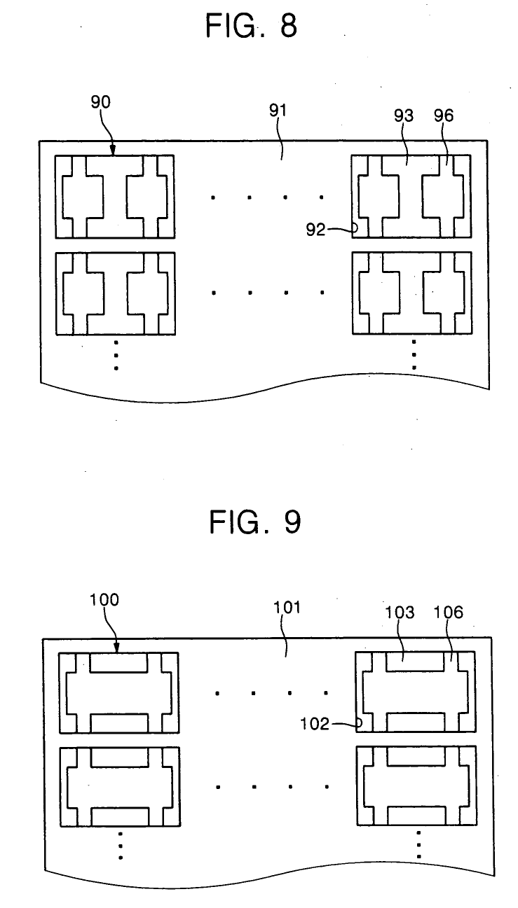

Referring to FIGS. 8 to 10, second to fourth condenser substrates 91, 101 and 111 are prepared. The second to fourth condenser substrates 91, 101 and 111 have second to fourth condenser plates 93, 103 and 113, respectively. The second to fourth condenser plates 93, 103 and 113 have different upper surfaces from the second to fourth condenser substrates 91, 101 and 111, respectively. At least one second condenser plate 93 is formed in a matrix on an upper surface of the second condenser substrate 91. At this time, preferably, each of the third and fourth condenser plates 103 and 113 are formed to correspond to the second condenser plates 93. Preferably, the second to fourth condenser plates 93, 103 and 113 and the second to fourth condenser substrates 91, 101 and 111 are formed of LTCC.

Meanwhile, second to fourth condenser regions 92, 102 and 112 may be set on the second to fourth condenser substrates 91, 101 and 111. The second to fourth condenser regions 92, 102 and 112 have the same upper surfaces as the second to fourth condenser substrates 91, 101 and 111. The same number of second condenser regions 92 as the second condenser plates 93 are formed on the second condenser substrate 91 to define the second condenser plates 93. The same number of third condenser regions 102 as the third condenser plates 103 are formed on the third condenser substrate 101 to define the third condenser plates 103. The same number of fourth condenser regions 112 as the fourth condenser plates 113 are formed on the fourth condenser substrate 111 to define the second condenser plates 113. At this time, the second to fourth condenser regions 92, 102 and 112 may be formed to have a predetermined area using a testing technique by dividing the second to fourth condenser substrates 91, 101 and 111. The second to fourth condenser regions 92, 102 and 112 may not be presented on the second to fourth condenser substrates 91, 101 and 111.

Upper, middle and lower condenser electrodes 96, 106 and 116 are formed on the second to fourth condenser plates 93, 103 and 113. Preferably, at least one upper condenser electrode 96 is formed on the second condenser plate 93. Preferably, at least one middle condenser electrode 106 is formed on the third condenser plate 103. Preferably, at least one lower condenser electrode 116 is formed on the fourth condenser plate 113. Preferably, the upper, middle and lower condenser electrodes 96, 106 and 116 are formed of a conductive material including silver (Ag). The second condenser plate 93 and the upper condenser electrode 96 constitute a second condenser means 90. The third condenser plate 103 and the middle condenser electrode 106 constitute a third condenser means 100. The fourth condenser plate 113 and the lower condenser electrode 116 constitute a fourth condenser means 110. On the other hand, the upper, middle and lower condenser electrodes 96, 106 and 116 may be formed on the second to fourth condenser regions 92, 102 and 112.

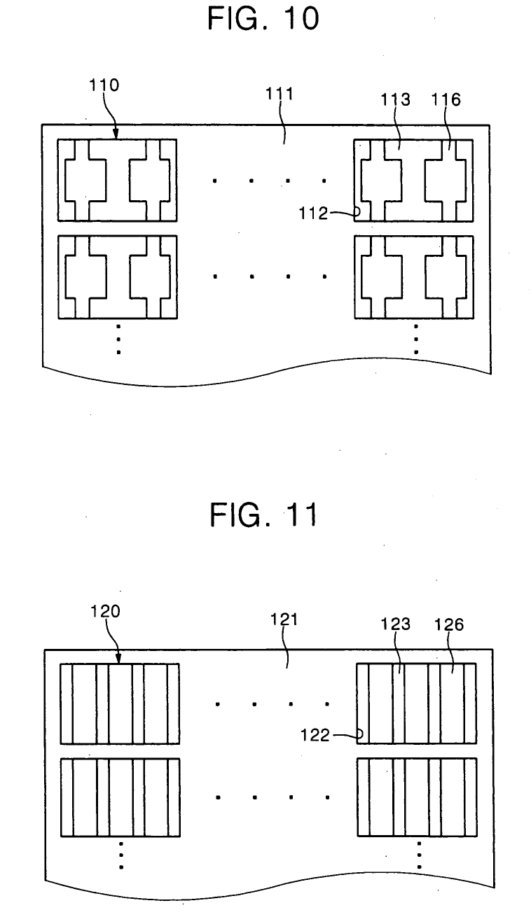

Referring to FIG. 11, a fifth condenser substrate 121 is prepared. The fifth condenser substrate 121 has a fifth condenser plate 123. The fifth condenser plate 123 and the fifth condenser substrate 121 have upper surfaces at different positions. At least one fifth condenser plate 123 is formed in a matrix on a lower surface of the fifth condenser substrate 121. At this time, preferably, the fifth condenser plates 123 are formed corresponding to the fourth condenser plates 113 of FIG. 10. Preferably, the fifth condenser plate 123 and the fifth condenser substrate 121 are formed of LTCC.

Meanwhile, fifth condenser regions 122 may be set on the fifth condenser substrate 121. The fifth condenser regions 122 and the fifth condenser substrate 121 have the same upper surface. The same number of fifth condenser regions 122 as the fifth condenser plates 123 are formed on the fifth condenser substrate 121 to define the fifth condenser plates 123. At this time, the fifth condenser regions 122 may be formed to have a predetermined area using a testing technique by dividing the fifth condenser substrate 121. The fifth condenser regions 122 may not be presented on the fifth condenser substrate 121.

Condenser terminal connection electrodes 126 are formed on the fifth condenser plate 123. In FIG. 1, when the cap terminal connection electrodes 16 are disposed in equal number directly across from one another at two opposite sides of the upper cap plate 13, the condenser terminal connection electrodes 126 are preferably disposed corresponding to each pair of directly opposite cap terminal connection electrodes. On the other hand, when the cap terminal connection electrodes 16 are disposed in equal number in a staggered fashion at two opposite sides of the upper cap plate 13, the condenser terminal connection electrodes 126 are preferably disposed corresponding to each cap terminal connection electrode. The condenser terminal connection electrodes 126 may be formed of a conductive material including silver (Ag). The fifth condenser plate 123 and the condenser terminal connection electrodes 126 constitute a fifth condenser means 120. On the other hand, the condenser terminal connection electrodes 126 may be formed on the fifth condenser region 122.

Referring to FIGS. 7 to 11, 16 and 17, an adhesive agent (not shown) may be interposed between the first to fifth condenser substrates 81, 91, 101, 111 and 121. The adhesive agent serves to adhere the upper surface of the second condenser substrate 91 to the lower surface of the first condenser substrate 81 and the upper surface of the third condenser substrate 101 to the lower surface of the second condenser substrate 91. In addition, the adhesive agent serves to adhere the upper surface of the fourth condenser substrate 111 to the lower surface of the third condenser substrate 101 and the upper surface of the fifth condenser substrate 121 to the lower surface of the fourth condenser substrate 111. At this time, preferably, the upper surfaces of the first to fourth condenser substrates 81, 91, 101 and 111 are oriented in the same direction. In addition, preferably, the upper surface and the lower surface of the fourth and fifth condenser substrates 111 and 121 are oriented in different directions. Preferably, the adhesive agent uses a non-conductive adhesive agent.

Meanwhile, sidewalls of the first to fifth condenser substrates 81, 91, 101, 111 and 121 may be aligned on the same line. Continuously, the first to fifth condenser substrates 81, 91, 101, 111 and 121 are cut along row and column directions (lines I-I′ and II-II′ of FIG. 7) to have widths larger than those of the first to fifth condenser plates 83, 93, 103, 113 and 123, thereby forming a condenser means 130 of FIG. 16. The first to fifth condenser substrates 81, 91, 101, 111 and 121 may be cut along row and column directions (lines I-I′ and II-II′ of FIG. 7) to have widths larger than those of the first to fifth condenser regions 82, 92, 102, 112 and 122, thereby forming the condenser means 130 of FIG. 16. As a result, the first to fifth condenser regions 82, 92, 102, 112 and 122 define the first to fifth condenser plates 83, 93, 103, 113 and 123.

The condenser means 130 includes the first to fifth condenser means 80, 90, 100, 110 and 120. The condenser means 130 has the vibration groove 86 in the first condenser means 80, the upper, middle and lower condenser electrodes 96, 106 and 116 in the second to fourth condenser means 90, 100 and 110, and the condenser terminal connection electrodes 126 in the fifth condenser means 120.

The vibration groove 86 is disposed between the resonance holes 69 of the lower resonance plate 63 of FIG. 6. The vibration groove 86 may be disposed to overlap the resonance holes 69 of the lower resonance plate 63, or partially overlap the resonance holes 69. At this time, the fifth condenser means 120 has the condenser terminal connection electrodes 126 on the fifth condenser plate 123 as shown in FIG. 17.

Referring to FIG. 18, the condenser means 130, the resonance means 70, and the cap means 30 are aligned to be sequentially deposited. An adhesive agent (not shown) may be interposed between the cap means 30, the resonance means 70, and the condenser means 130. Preferably, the adhesive agent uses a non-conductive adhesive agent. At this time, the resonance means 70 is adhered to the cap means 30 and the condenser means 130 at its upper and lower surfaces. As a result, the vibration groove 86 of the first condenser plate 83 faces the vibration groove 26 of the lower cap plate 23.

Connection wires 140 are formed to connect the cap terminal connection electrodes 16 of the upper cap plate 13 and the condenser terminal connection electrodes 126 of the fifth condenser plate 123. The connection wires 140 are in contact with both sidewalls of the upper and lower cap plates 13 and 23, and both sidewalls of the upper, middle and lower resonance plates 43, 53 and 63, and first to fifth condenser plates 83, 93, 103, 113 and 123, which are corresponding to the sidewalls of the upper and lower cap plates 13 and 23. At this time, the connection wires 140 are in contact with the upper, middle and lower resonance electrodes 46, 56 and 66, and the upper, middle and lower condenser electrodes 96, 106 and 116. Preferably, the connection wires 140 are formed of a conductive material including tin (Sn). As a result, the connection wires 140 are electrically connected to the condenser means 130, the resonance means 70 and the cap means 30 to complete the surface mounted resonator 150.

As can be seen from the foregoing, the present invention provides a surface mounted resonator having a cap means and a method of forming the same using an insulating ceramic substrate. Therefore, it is possible to simplify a process of fabricating the surface mounted resonator having the cap means including the insulating ceramic substrate.

Although a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A surface mounted resonator comprising:
a cap means having upper and lower cap means, wherein the lower cap means has a vibration groove and the upper cap means has cap terminal connection electrodes;
a resonance means disposed under the cap means and including upper, middle and lower resonance means, each of which has resonance electrodes and resonance holes disposed around the resonance electrodes;
a condenser means having first to fifth condenser means sequentially stacked under the resonance means, wherein the first condenser means has another vibration groove, the second to fourth condenser means have condenser electrodes, and the fifth condenser means has condenser terminal connection electrodes; and
connection wires for connecting the condenser terminal connection electrodes and the cap terminal connection electrodes,
wherein the connection wires are disposed in contact with the resonance electrodes and the condenser electrodes, the vibration grooves in the first condenser means and the lower cap means are opposite to each other, and the resonance means is disposed in contact with the cap means and the condenser means at upper and lower surfaces.

2. The surface mounted resonator according to claim 1, further comprising upper and lower cap plates respectively disposed in the upper and lower cap means, and first to fifth condenser plates respectively disposed in the first to fifth condenser means,
wherein the condenser terminal connection electrodes and the cap terminal connection electrodes are disposed on an upper surface of the fifth condenser plate and on a lower surface of the upper cap plate, respectively, the cap terminal connection electrodes are disposed in equal number directly across from one another at two opposite sides of the upper cap plate, and the condenser terminal connection electrodes are disposed corresponding to each pair of directly opposite cap terminal connection electrodes.

3. The surface mounted resonator according to claim 2, wherein the vibration grooves are disposed at a lower surface of the lower cap plate and an upper surface of the first condenser plate, respectively.

4. The surface mounted resonator according to claim 2, wherein the upper and lower cap plates are in contact with each other and disposed in the cap means.

5. The surface mounted resonator according to claim 2, wherein the first to fifth condenser plates are in contact with each other and disposed in the condenser means.

6. The surface mounted resonator according to claim 2, further comprising upper, middle and lower resonance plates disposed in the upper, middle and lower resonance means, respectively,
wherein at least one resonance electrode is disposed on each of the upper, middle and lower resonance plates, the middle resonance plate contacts the upper and lower resonance plates at upper and lower surfaces to be disposed in the resonance means, each of the second to fourth condenser plates has at least one condenser electrode, and thickness of the upper resonance plate is the same as the sum of thicknesses of the middle and lower resonance plates.

7. The surface mounted resonator according to claim 6, wherein each of the resonance electrodes has a shape of “ [symbol] ” or “ [symbol] ”, the resonance electrode of the upper resonance plate and the resonance electrode of the middle resonance plate are disposed in a direction perpendicular to both sides of the upper cap plate to have shapes of “ [symbol] ” and “ [symbol] ” so that the electrodes are alternately disposed on the upper surfaces of the upper and middle resonance plates, and the resonance electrode of the lower resonance plate is positioned in a direction parallel to the upper resonance electrode to have a shape of “ [symbol] ” to be disposed on a lower surface of the lower resonance plate.

8. The surface mounted resonator according to claim 7, wherein each of the upper, middle and lower resonance plates has at least two resonance holes to overlap through the upper, middle and lower resonance plates.

9. The surface mounted resonator according to claim 8, wherein the resonance holes of the upper and lower resonance plates are disposed around the vibration grooves of the lower cap plate and the first condenser plate.

10. The surface mounted resonator according to claim 8, wherein the resonance holes of the upper and lower resonance plates are disposed to overlap the vibration grooves of the lower cap plate and the first condenser plate.

11. The surface mounted resonator according to claim 8, wherein the resonance holes of the upper and lower resonance plates are disposed to partially overlap the vibration grooves of the lower cap plate and the first condenser plate.

12. The surface mounted resonator according to claim 8, wherein the condenser electrodes, the resonance electrodes, the condenser terminal connection electrodes, the cap terminal connection electrodes, and the connection wires are formed of a conductive material.

13. The surface mounted resonator according to claim 12, wherein the upper and lower cap plates, and the first to fifth condenser plates are formed of low temperature cofired ceramic (LTCC).

14. The surface mounted resonator according to claim 13, wherein the upper, middle and lower resonance plates are formed of PbZrTiO₃ (PZT).

15. The surface mounted resonator according to claim 1, further comprising upper and lower cap plates respectively disposed in the upper and lower cap means, and first to fifth condenser plates respectively disposed in the first to fifth condenser means,
wherein the condenser terminal connection electrodes and the cap terminal connection electrodes are disposed on an upper surface of the fifth condenser plate and on a lower surface of the upper cap plate, respectively, the cap terminal connection electrodes are disposed in equal number in a staggered fashion at two opposite sides of the upper cap plate, and the condenser terminal connection electrodes are disposed corresponding to each cap terminal connection electrode.

16. The surface mounted resonator according to claim 15, wherein the vibration grooves are disposed at a lower surface of the lower cap plate and an upper surface of the first condenser plate, respectively.

17. The surface mounted resonator according to claim 15, wherein the upper and lower cap plates are in contact with each other and disposed in the cap means.

18. The surface mounted resonator according to claim 15, wherein the first to fifth condenser plates are in contact with each other and disposed in the condenser means.

19. The surface mounted resonator according to claim 15, further comprising upper, middle and lower resonance plates disposed in the upper, middle and lower resonance means, respectively,
wherein at least one resonance electrode is disposed on each of the upper, middle and lower resonance plates, the middle resonance plate contacts the upper and lower resonance plates at upper and lower surfaces to be disposed in the resonance means, each of the second to fourth condenser plates has at least one condenser electrode, and thickness of the upper resonance plate is the same as the sum of thicknesses of the middle and lower resonance plates.

20. The surface mounted resonator according to claim 19, wherein each of the resonance electrodes has a shape of “ [symbol] ” or a “ [symbol] ”, the resonance electrode of the upper resonance plate and the resonance electrode of the middle resonance plate are disposed in a direction perpendicular to both sides of the upper cap plate to have shapes of “ [symbol] ” and “ [symbol] ” so that the electrodes are alternately disposed on the upper surfaces of the upper and middle resonance plates, and the resonance electrode of the lower resonance plate is positioned in a direction parallel to the upper resonance electrode to have a shape of “ [symbol] ” to be disposed on a lower surface of the lower resonance plate.

21. The surface mounted resonator according to claim 20, wherein each of the upper, middle and lower resonance plates has at least two resonance holes to overlap through the upper, middle and lower resonance plates.

22. The surface mounted resonator according to claim 21, wherein the resonance holes of the upper and lower resonance plates are disposed around the vibration grooves of the lower cap plate and the first condenser plate.

23. The surface mounted resonator according to claim 21, wherein the resonance holes of the upper and lower resonance plates are disposed to overlap the vibration grooves of the lower cap plate and the first condenser plate.

24. The surface mounted resonator according to claim 21, wherein the resonance holes of the upper and lower resonance plates are disposed to partially overlap the vibration grooves of the lower cap plate and the first condenser plate.

25. The surface mounted resonator according to claim 20, wherein the condenser electrodes, the resonance electrodes, the condenser terminal connection electrodes, the cap terminal connection electrodes, and the connection wires are formed of a conductive material.

26. The surface mounted resonator according to claim 25, wherein the upper and lower cap plates, and the first to fifth condenser plates are formed of low temperature cofired ceramic (LTCC).

27. The surface mounted resonator according to claim 26, wherein the upper, middle and lower resonance plates are formed of PbZrTiO₃ (PZT).

28. A method of forming a surface mounted resonator, comprising:
forming a cap means having upper and lower cap means, wherein the lower cap means has a vibration groove and the upper cap means has cap terminal connection electrodes;
forming a resonance means disposed under the cap means and having upper, middle and lower resonance means, each of which has resonance electrodes and resonance holes around the resonance electrodes;
forming a condenser means having first to fifth condenser means sequentially stacked under the resonance means, wherein the first condenser means has another vibration groove, the second to fourth condenser means have condenser electrodes, and the fifth condenser means has condenser terminal connection electrodes; and
forming connection wires for connecting the condenser terminal connection electrodes and the cap terminal connection electrodes,
wherein the connection wires are disposed in contact with the resonance electrodes and the condenser electrodes, the vibration grooves in the first condenser means and the lower cap means are opposite to each other, and the resonance means is disposed in contact with the cap means and the condenser means at upper and lower surfaces.

29. The method according to claim 28, further comprising forming first to fifth condenser plates in the first to fifth condenser means, upper, middle and lower resonance plates in the upper, middle and lower resonance means, and upper and lower cap plates in the upper and lower cap means,
wherein the connection wires are in contact with directly opposite locations on two opposite sidewalls of the upper and lower cap plates, the upper, middle and lower resonance plates corresponding to each pair of directly opposite locations where the connection wires are in contact with the two sidewalls of the upper and lower cap plates, and the first to fifth condenser plates corresponding to each pair of directly opposite locations where the connection wires are in contact with the two sidewalls of the upper and lower cap plates, and the vibration grooves are formed at the lower cap plate and the fifth condenser plate.

30. The method according to claim 29, wherein the condenser terminal connection electrodes are formed on the fifth condenser plate, the condenser electrodes are formed on the second to fourth condenser plates, the resonance electrodes are formed on the upper, middle and lower resonance plates, and the cap terminal connection electrodes are formed on the upper cap plate.

31. The method according to claim 30, wherein the cap terminal connection electrodes are disposed in equal number directly across from one another at two opposite sides of the upper cap plate, and the condenser terminal connection electrodes are disposed corresponding to each pair of directly opposite cap terminal connection electrodes.

32. The method according to claim 31,
wherein each of the resonance electrodes is disposed to have a shape of “ [symbol] ” or “ [symbol] ”, the resonance electrode of the upper resonance plate and the resonance electrode of the middle resonance plate are disposed in a direction perpendicular to both sides of the upper cap plate to have shapes of “ [symbol] ” and “ [symbol] ” so that the electrodes are alternately disposed on the upper surfaces of the upper and middle resonance plates, and the resonance electrode of the lower resonance plate is positioned in a direction parallel to the upper resonance electrode to have a shape of “ [symbol] ” to be disposed on a lower surface of the lower resonance plate.

33. The method according to claim 32, wherein each of the upper, middle and lower resonance plates has at least two resonance holes to overlap through the upper, middle and lower resonance plates.

34. The method according to claim 33, wherein the resonance holes of the upper and lower resonance plates are disposed around the vibration grooves.

35. The method according to claim 33, wherein the resonance holes of the upper and lower resonance plates are disposed to overlap the vibration grooves.

36. The method according to claim 33, wherein the resonance holes of the upper,and lower resonance plates are disposed to partially overlap the vibration grooves.

37. The method according to claim 33, wherein the condenser electrodes, the resonance electrodes, the condenser terminal connection electrodes, the cap terminal connection electrodes, and the connection wires are formed of a conductive material.

38. The method according to claim 37, wherein the upper and lower cap plates, and the first to fifth condenser plates are formed of low temperature cofired ceramic (LTCC).

39. The method according to claim 38, wherein the upper, middle and lower resonance plates are formed of PbZrTiO₃ (PZT).

40. The method according to claim 30, wherein the cap terminal connection electrodes are disposed in equal number in a staggered fashion at two opposite sides of the upper cap plate, and the condenser terminal connection electrodes are disposed corresponding to each cap terminal connection electrode.

41. The method according to claim 40, wherein each of the resonance electrodes is disposed to have a shape of “ [symbol] ” or “ [symbol] ”, the resonance electrode of the upper resonance plate and the resonance electrode of the middle resonance plate are disposed in a direction perpendicular to both sides of the upper cap plate to have shapes of a “ [symbol] ” and “ [symbol] ” so that the electrodes are alternately disposed on the upper surfaces of the upper and middle resonance plates, and the resonance electrode of the lower resonance plate is positioned in a direction parallel to the upper resonance electrode to have a shape of “ [symbol] ” to be disposed on a lower surface of the lower resonance plate.

42. The method according to claim 41, wherein each of the upper, middle and lower resonance plates has at least two resonance holes to overlap through the upper, middle and lower resonance plates.

43. The method according to claim 42, wherein the resonance holes of the upper and lower resonance plates are disposed around the vibration grooves.

44. The method according to claim 42, wherein the resonance holes of the upper and lower resonance plates are disposed to overlap the vibration grooves.

45. The method according to claim 42, wherein the resonance holes of the upper and lower resonance plates are disposed to partially overlap the vibration grooves.

46. The method according to claim 42, wherein the condenser electrodes, the resonance electrodes, the condenser terminal connection electrodes, the cap terminal connection electrodes, and the connection wires are formed of a conductive material.

47. The method according to claim 46, wherein the upper and lower cap plates, and the first to fifth condenser plates are formed of low temperature cofired ceramic (LTCC).

48. The method according to claim 47, wherein the upper, middle and lower resonance plates are formed of PbZrTiO₃ (PZT).

49. The method according to claim 28, wherein forming the condenser means comprises:
preparing first to fifth condenser substrates;
forming at least one first condenser plate in a matrix on an upper surface of the first condenser substrate;
forming the same number of second to fourth condenser plates as the first condenser plates on upper surfaces of the second to fourth condenser substrates, respectively;
forming the same number of fifth condenser plate as the first condenser plate on a lower surface of the fifth condenser substrate;
adhering the first to fifth condenser substrates to each other; and
cutting the first to fifth condenser substrates along row and column directions to have widths larger than those of the first to fifth condenser plates;
wherein the upper surfaces of the first to fourth condenser substrates are oriented in the same direction, and the upper surface of the fourth condenser substrate and the lower surface of the fifth condenser substrate are oriented in different directions.

50. The method according to claim 28, wherein forming the resonance means comprises:
preparing upper, middle and lower resonance substrates;
forming at least one upper resonance plate in a matrix on an upper surface of the upper resonance substrate;
forming the same number of middle and lower resonance plates as the upper resonance plates on upper and lower surfaces of the middle and lower resonance substrates, respectively;
adhering the upper, middle and lower resonance substrates to each other; and
cutting the upper, middle and lower resonance substrates along row and column directions to have widths larger than those of the upper, middle and lower resonance plates,
wherein the upper surfaces of the upper and middle resonance substrates are oriented in the same direction, and the upper surface of the middle resonance substrate and the lower surface of the lower resonance substrate are oriented in different directions, and the sum of thicknesses of the upper resonance substrate and resonance plate is the same as that of the middle and lower resonance substrates, and the middle and lower resonance plates.

51. The method according to claim 28, wherein forming the cap means comprises;
preparing upper and lower cap substrates;
forming at least one upper cap plate in a matrix on an upper surface of the upper cap substrate;
forming the same number of lower cap plates as the upper cap plates on a lower surface of the lower cap substrate;
adhering the upper and lower cap substrates to each other; and
cutting the upper and lower cap substrates along row and column directions to have widths larger than those of the upper and lower cap plates,
wherein the upper and lower surfaces of the upper and lower cap substrates are oriented different directions.
